(19) United States
(12) Patent Application Publication
(10) Pub. No.: US 2026/0328824 A1
(43) Pub. Date: Oct. 22, 2026

(54) ANTENNA CHARACTERISATION USING SPATIAL SAMPLING

(71) Applicant: HAUTE ECOLE D'INGÉNIERIE ET DE GESTION DU CANTON DE VAUD (HEIG-VD), Yverdon-les-Bains (CH)

(72) Inventor: Mohammad AZADIFAR, Ecublens (CH)

(21) Appl. No.: 19/122,692

(22) PCT Filed: Oct. 31, 2022
(86) PCT No.: PCT/EP2022/080356

§ 371 Date: Apr. 18, 2025

(51) Int. Cl. G01R 29/10; G01R 29/08; H04B 17/10; H04B 17/27

(52) U.S. Cl. CPC G01R 29/10; G01R 29/0892; H04B 17/101; H04B 17/27

(57) ABSTRACT

A method for localising and characterising one or more electromagnetic radiation sources is proposed. The method comprises the steps of: measuring one or more electrical signals received from the one or more sources placed in an observation region in front of a sampling apparatus; time-reversing the measured one or more electrical signals; inputting the one or more time-reversed electrical signals into an electromagnetic field solver modelling the sampling apparatus, and configured to solve Maxwell's equations; determining a reconstructed electromagnetic field by running the electromagnetic field solver with the one or more time-reversed electrical signals as one or more input signals; identifying one or more focal spots in the reconstructed electromagnetic field to thereby locate one or more modelled sources in a simulated observation region; and obtaining a respective far-field radiation pattern for the one or more modelled sources directly or indirectly from the reconstructed electromagnetic field.

### TECHNICAL FIELD

The present invention lies in the field of antenna characterisation. More specifically, the present invention relates to a method of localising electromagnetic sources and finding their radiation patterns. The invention also relates to a corresponding apparatus and system for implementing the method.

### BACKGROUND OF THE INVENTION

With the advent of modern wireless communication systems, such as 5G and internet of things (IoT), and the paradigm shift towards millimetre-wave communications, antenna pattern and radiated emission measurements are necessary steps in design and validation processes of wireless systems.

Mechanical rasterised scanning is currently the most widely used technique for electromagnetic interference (EMI) measurements or antenna source localisation, characterisation or far-field pattern measurements, where a positioning robot is used to measure the gain of the antenna source in the far field. In the case of far-field scanning, the measurement must be conducted iteratively for various angles of incidence to provide a full three-dimensional (3D) pattern of the antenna under test. These types of measurements are time-consuming, and they may also get very complex with narrow beams and beamforming schemes. At millimetre wavelength, achieving precise positioning may also turn out to be challenging.

Near-field scanning methods, which are developed based on plane wave spectrum representation of an electromagnetic field, are also used to detect and characterise electromagnetic sources. A two-dimensional (2D) robot scanner is used to position a probe to measure the field components close to the surface of the source, and the near-field to far-field transformation is used to reconstruct the antenna pattern. This method can provide very high-resolution results for source detection. However, there is still a need to carry out mechanical scanning and one needs to minimise the effect of the probe and its interaction with the emitting source or antenna under test.

More recently, wired metalenses along with compressive sensing was used to localise sources, a technique which beats the diffraction limit. However, due to the placement of the source in the vicinity of the wired metalens, and near-field interaction of the metalens and the source antenna, one could not recover the exact content of the field due to the near-field interaction.

### SUMMARY OF THE INVENTION

It is an object of the present invention to overcome at least some of the problems identified above related to localising and characterising an electromagnetic radiation source, as well as to retrieving its radiation pattern. The present invention thus aims to propose a hardware element and a method which can localise and characterise an electromagnetic radiation source, such as an antenna, as well as retrieve its radiation pattern using spatial sampling.

According to a first aspect of the invention, there is provided a method of localising and characterising an electromagnetic radiation source as recited in claim 1.

The present invention proposes a novel technique to locate and characterise electromagnetic radiation sources using the concept of spatial sampling. The proposed method allows radiation sources to be localised and characterised very precisely without carrying out any scanning operation of the radiation fields. Furthermore, the proposed method does not need to use lots of sensors or robotic arms, and it provides a quick measurement compared to the conventional point to point scanning methods. The sampling arrangement used by the proposed method can also be made more compact than the arrangements used in currently known solutions. More, specifically, according to the present invention, the distance between the source antenna and the front face of the sampling apparatus can be as low as 0.62×sqrt(D³/π) compared to the minimum distance of 2×D²/λ in current solutions, where D denotes the greatest dimension of the source antenna, and λ denotes the wavelength of the signal radiated by the source antenna.

According to a second aspect of the invention, there is provided a non-transitory computer program product comprising instructions for implementing the steps of the method according to any one of the preceding claims when loaded and run on computing means of a computing device.

According to a third aspect of the invention, there is provided a sampling apparatus for sampling an electromagnetic field as recited in claim 12.

According to a fourth aspect of the invention, there is provided a system for localising and characterising one or more electromagnetic radiation sources as recited in claim 16.

Other aspects of the invention are recited in the dependent claims attached hereto.

### BRIEF DESCRIPTION OF THE DRAWINGS

Other features and advantages of the invention will become apparent from the following description of a non-limiting example embodiment, with reference to the appended drawings, in which:

FIG. 1 shows a measurement arrangement or system for localising and characterising an electromagnetic radiation source;

FIG. 2 shows a measurement apparatus that may be used to sample an electromagnetic field generated by an electromagnetic radiation source;

FIG. 3 shows the return loss measured for an example half-wave dipole antenna to be localised;

FIG. 4 shows a time-reversed version of a measured electrical signal for the dipole antenna to be localised;

FIG. 5 shows the normalised maximum value of E_{y} in the plane of observation over all of the time samples once a simulation model has been excited with the time-reversed version of the measured signal as shown in FIG. 4;

FIG. 6 shows the normalised maximum value of E_{y} over all of the time samples along the X-axis at y=E_{y,max} in the scenario of FIG. 5;

FIG. 7 shows the normalised maximum value of Eₓ in the plane of observation over all of the time samples once a simulation model has been excited with the time-reversed version of the measured signal as shown in FIG. 4, but where the antenna to be localised has been rotated by 90° compared to the scenario of FIG. 5;

FIG. 8 illustrates the comparison of a normalised excitation signal of the dipole antenna with a normalised reconstructed waveform;

FIG. 9 shows the return loss measured for an example patch antenna to be localised and the structure of the patch antenna;

FIGS. 10a and 10b show the distribution of the normalised maximum Eₓ component in an X-Y plane placed 5 mm away from the plane of observation of the patch antenna of FIG. 9 towards a sampling apparatus, and the distribution of the normalised maximum reconstructed Eₓ in the plane of observation, respectively;

FIGS. 10c and 10d show the distribution of the normalised maximum E_{y} component in an X-Y plane placed 5 mm away from the plane of observation of the patch antenna of FIG. 9 towards the sampling apparatus, and the distribution of the normalised maximum reconstructed E_{y} in the plane of observation, respectively;

FIG. 11 shows the comparison of directivity for direct calculations and the reconstructed ones for electric and magnetic fields at 21.5 GHz for the patch antenna of FIG. 9;

FIGS. 12a and 12b provide the direct calculation of the 3D normalised total radiated power, and the reconstructed one at 21.5 GHz for the patch antenna of FIG. 9, respectively; and

FIGS. 13a and 13b is a flow chart illustrating the steps of the proposed method to localise and characterise one or more electromagnetic radiation sources.

### DETAILED DESCRIPTION OF AN EMBODIMENT OF THE INVENTION

An embodiment of the present invention will now be described in detail with reference to the attached figures. Identical or corresponding functional and structural elements which appear in the different drawings are assigned the same reference numerals.

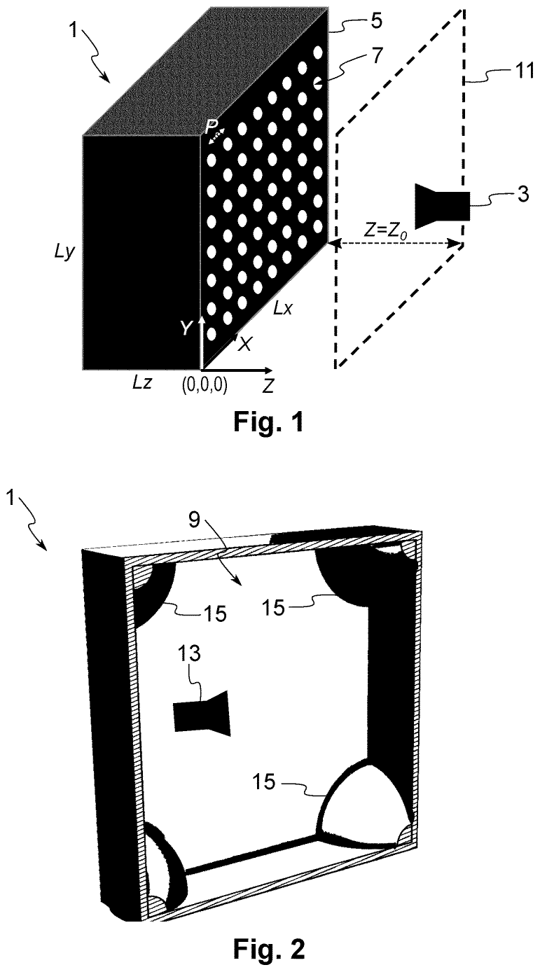

FIG. 1 illustrates the measurement arrangement or set-up for measuring an electromagnetic field resulting from an electromagnetic radiation source, such as an antenna. A sampling apparatus 1 is configured to carry out spatial sampling of the electromagnetic field which is generated by a radiation source 3 placed at a distance Z₀ from a front surface 5 of the sampling apparatus 1. The sampling apparatus, which is better shown in FIG. 2 without its front face 5, comprises a resonant cavity structure.

The dimensions of the cavity are advantageously chosen so that the first resonance frequency of the cavity is higher than the frequency range of the source (i.e., the range of frequencies of the signal radiated by the source). This means that the length of each dimension (in this case length, height, and width) of the cavity at least equals the wavelength of the electromagnetic radiation emitted by the source. The front face or surface 5, which in operation is facing the source 3, comprises an array of holes or perforations. The sampling apparatus, and in particular the front face may instead or additionally comprise an electromagnetic metasurface. The metasurface can be any structure with sub-wavelength-sized uniform or non-uniform patterns. This metasurface has the property of creating an electric field at the plane of observation with low spatial autocorrelation. In this example, the holes 7 or perforations, which are through holes, are arranged in a periodic array, with a given spatial separation between any two adjacent holes. In this example, a rounded shape 15, which is an optional feature, is provided at one or more of the inner corners of the cavity 9 as shown in FIG. 2. The rounded shapes may for example be spherical or elliptical shapes. However, any other shape, such as an elongated rod, may be used, and it/they can be placed in any location within the cavity. The one or more shapes 15 serve as one or more mode-mixing features or structures 15 provided within the cavity to enhance the mixing-mode nature of the cavity. In this example, a plane of observation 11 or more broadly an observation region is considered to be at a far-field distance from the cavity in the X-Y plane (but this does not have to be the case), which is defined by the front face 5. The L_{z} dimension is the thickness of the sampling apparatus. The one or more sources to be detected and/or characterised is/are placed in the plane of observation 11 or inside the observation region (which may define a three-dimensional volume). The emitted electromagnetic field from the source will reach the front face 5 of the cavity at Z=0.

As also shown in FIG. 2, the sampling apparatus thus comprises a solid object or body, with a cavity within the body, and one or more sensors 13 or probes provided within the cavity. The body forms in this example a substantially closed body (i.e., a body which is closed on all sides), with a perforated front face. This sampling apparatus is in this case made of a metallic element, but the sampling apparatus could instead be made of any electrically conductive material. Furthermore, when ignoring the shapes 15, the cavity is in this example of a rectangular shape, but other cavity shapes are also possible. As will become clear later, the cavity 9 can be considered as a time-reversal mirror. Reflections from the surfaces of the cavity can emulate an infinite number of sensors in the time-reversal method. By using only one sensor, it is possible to locate electromagnetic sources by taking advantage of the focusing properties of the time-reversal cavity.

The boundary condition forces

$${E}_{z = 0 +}^{1} = {E}_{Z = 0 -}^{2} = 0$$

on the front face of the cavity, except at the positions of the holes 7.

$${E}_{z = 0 +}^{1}$$

denotes the electric field component that is tangential to the X-Y plane when Z≥0, while

$${E}_{Z = 0 -}^{2}$$

denotes the electric field component that is tangential to the X-Y plane when Z<0. At the positions of the holes, we can write

$${E}_{z = 0 +}^{1} = {E}_{Z = 0 -}^{2}$$

or more thoroughly, we have:

$${E}_{y}^{1} = {E}_{y}^{2} , {E}_{x}^{1} = {E}_{x}^{2}$$

$${H}_{y}^{1} = {H}_{y}^{2} , {H}_{x}^{1} = {H}_{x}^{2}$$

$$due to {J}_{x} = {J}_{y} = 0$$

$${H}_{z}^{1} = {H}_{z}^{2} , {E}_{z}^{1} = {E}_{z}^{2}$$

In the above equations, the superscript “1” refers to the situation where Z≥0, while the superscript “2” refers to the situation where Z<0, E denotes the electric field, H denotes the magnetic field, J denotes the electric current density, x refers to the component along the X-axis, y refers to the component along the Y-axis, while z refers to the component along the Z-axis.

According to the Bethe theory of diffraction for small holes, H. A. Bethe, “Theory of diffraction by small holes,” Phys. Rev., vol. 66, no. 7-8, pp. 163-182, October 1944, the diameter of the holes should be small compared to the measured wavelength. Hence, it can be assumed that the field does not vary within any given hole. On the other hand, the size of the holes cannot be too small, as this would lead to only a small amount of the electromagnetic field coupling to the interior side of the cavity. In the concrete example explained below, we considered the hole diameter to be about λₘᵢₙ/2, where λₘᵢₙ denotes the minimum wavelength of the electromagnetic radiation emitted by the source 3. It is to be noted that the hole diameter is preferably a value taken from the range of λₘᵢₙ/5 to λₘᵢₙ/2 or more specifically in the range of λₘᵢₙ/4 to λₘᵢₙ/2. It is to be noted that the cross section of the holes does not have to be circular, but any other cross-sectional hole shapes in the X-Y plane are possible. Thus, the diameter may be understood to mean the greatest cross-sectional dimension of the holes.

As shown in FIG. 1, an array of holes was thus deployed on the front wall of the cavity. This array of holes can be understood to form of a spatial field sampler which can be used instead of deploying numerous arrays of field sensors or instead of using a rasterised scanner.

Let us imagine this problem in the frequency domain. The front face 5 of the cavity 9 is in this example in the far-field region of the source 3, and we can consider the plane-wave approximation for the field distribution at Z=0. In this case, the transversal size of the cavity (in the X-Y plane) is more than several λₘᵢₙ. Hence, enough spatial sampling points are needed to ensure the spatial Nyquist rate. Furthermore, in this example, the spatial sampling period, i.e., the spatial separation between any two adjacent holes, is set to λₘᵢₙ/2.

Once the field has been sampled by the front face of the cavity, we can consider using the electromagnetism uniqueness theorem and obtain the magnetic current sources at the locations of the holes 7 on the interior surface of the cavity 9. The electromagnetism uniqueness theorem states that providing boundary conditions for Maxwell's equations uniquely fixes a solution for those equations. Because Maxwell's equations fully characterise all electromagnetic interactions, they also accommodate the existence of electromagnetic sources. There are two principal types of electromagnetic sources, namely electrical sources and magnetic sources. In Maxwell's equations, electrical sources are represented using a current density, which has a unit A/m², while the magnetic source is a magnetic flux density, which has a unit T. Furthermore, the strong mode-mixing feature of chaotic microwave cavities is a well-established fact. Considering only plane wave field propagation in a chaotic cavity, the field at each location inside the cavity can be seen as a superposition of numerous rays with different phases and directions.

Each of the magnetic current sources at each hole location produces rays in all directions inside the cavity and excites both chaotic and bouncing ball modes of the cavity (see K. Selemani, J. B. Gros, E. Richalot, O. Legrand, O. Picon, and F. Mortessagne, “Comparison of reverberation chamber shapes inspired from chaotic cavities,” IEEE Trans. Electromagn. Compat., vol. 57, no. 1, pp. 3-11, February 2015 for the definition of these modes). We measure the field inside the cavity by means of the one or more sensors 13, and these rays will reach our measurement point(s) (i.e., the sensor locations) via numerous paths and contribute to the overall recorded field or signal at the measurement point(s). In other words, the field sampled by the holes 7 of the front face 5 of the cavity 9 couples strongly with the modes of the cavity.

In the next step, the proposed method uses time-reversal processing to decode the information in the measured or recorded electrical signal at the measurement point(s). In other words, the time-reversal processing is used to decode the hidden information in the field inside the cavity. In the time-reversal processing, we remove the original source 3 to be detected and characterised from the solution space, and we time-reverse the signal and inject it to an electromagnetic field solver, which is a computer simulation model. The solver models the sampling apparatus, and it is configured to solve Maxwell's equations. An example of such as a solver is given for example in a publication by Oskooi, Ardavan F., et al. “MEEP: A flexible free-software package for electromagnetic simulations by the FDTD method”, Computer Physics Communications 181.3 (2010): 687-702. The solver is calibrated with at least the dimensions and geometry of the sampling apparatus 1, and in particular the dimensions and geometry of the cavity 9. By observing the field components in the plane of observation 11, the source 3 can be located and characterised.

Time-reversal or T-symmetry describes the symmetry of physical laws under a time-reversal transformation: t→−t. The time-reversal operation causes the original signal to flip with respect to its amplitude axis (i.e., typically the vertical axis of reference). This means that the operation results in the reflection of the signal along its amplitude axis of reference (i.e., typically the vertical axis of reference). The operation is known as the time-reversal or time reflection of the signal. In the past couple of decades, the technique has found many applications in the field of engineering, especially in source-location identification such as landmine detection and fault location in power networks.

The time-reversal operation in signal processing can be understood as a spatial focusing technique that uses the reciprocity principle. Let us imagine a signal that is sent out from a transmit location, which in the present invention is an antenna to be localised and characterised. The signal can be picked up at several receive locations (i.e., the sensor locations). The sensors also record these received signals. Now the system can be visualised in reverse. The previous receive locations can become transmit locations. These locations (when transposed to a simulation model as explained later), transmit the previously recorded signals simultaneously but in a time-reversed manner. At the target locations in the model (corresponding to the original transmitters or the antennas in the present case), all the signals converge or focus in space (i.e., convergence location(s) in the model).

An example numerical model is explained in the following. In this study we performed both the forward propagation and backward propagation using a transient electromagnetic field solver. This solver uses the finite integration technique (FIT) to solve the Maxwell's equations in their integral form. It is worth noting that in a practical scenario, the forward propagation will be analysed via measurements and the back propagation will be analysed by using numerical simulation with the solver.

First, details of the implemented structure are presented. Thereafter, we show case studies for the use of the presented concept for source localisation, surface current reconstruction, and far-field pattern reconstruction. The implemented geometry is shown in FIGS. 1 and 2. The diameter of the holes is 5 mm. The number of holes along the X and Y axes is 17 (i.e., in total 17×17 holes) and they are placed with a periodicity of 10 mm from each other. The size of the cavity itself is 200 mm×200 mm×53 mm. The radius of the spheres is 45 mm. The plane of observation is located at Z=60 mm, which is further than the far-field limit of 2D²/λ where D denotes the maximum dimension of the source. The length of the receiving probe antenna is 6.4 mm, and it is located at −50 mm, −50 mm, −26.5 mm from the centre of the front face 5 of the cavity 9.

### Source Localisation

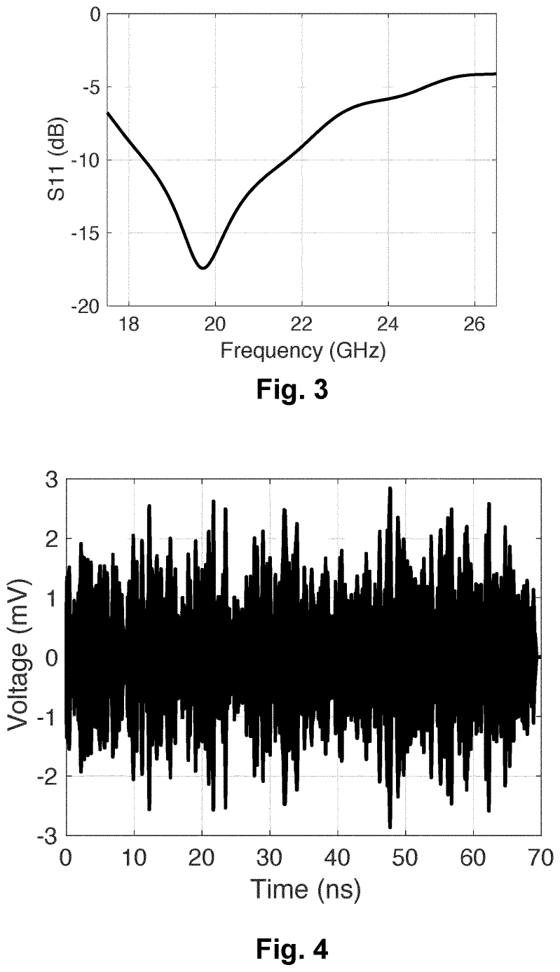

As a first example, a half-wave dipole antenna is considered as the radiator to be localised. The length of the antenna in this example is 6.4 mm. The return loss of the dipole antenna as measured at the input of the source antenna is presented in FIG. 3. We placed this dipole antenna at the plane of observation at x=50 mm and y=50 mm extending along the Y-axis. The dipole antenna was excited with a gaussian waveform with a bandwidth of 17.5 to 26.5 GHz. The signal emitted by this dipole is recorded with our probe antenna located at x=−50 mm, y=−50 mm, z=−26.5 mm extending along the Y-axis. The time-reversed version of the recorded signal is shown in FIG. 4.

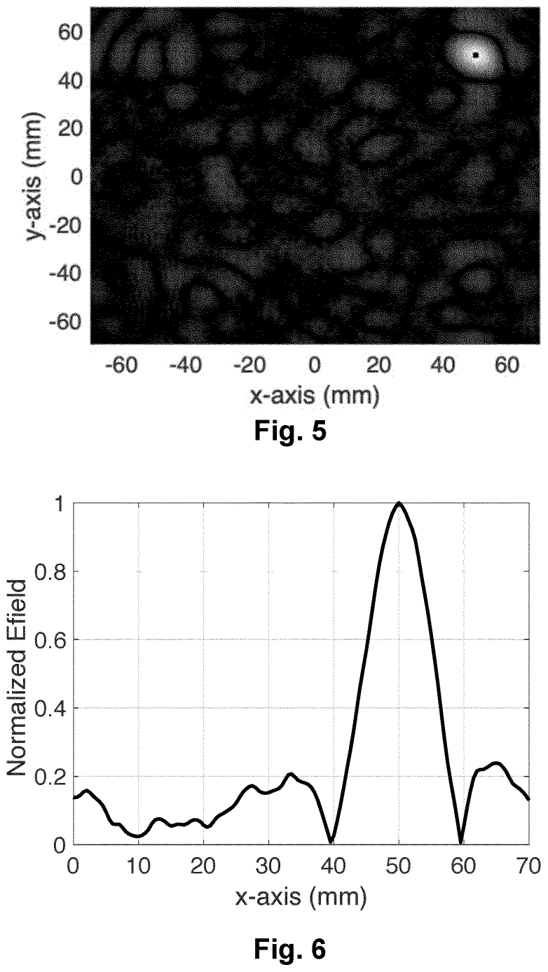

In the next step, we removed the source from the plane of observation, and we excited the electromagnetic field solver with the time-reversed version of the recorded signal shown in FIG. 4. FIG. 5 shows the maximum value of E_{y} in the plane of observation over all the time samples. We can see that the field refocuses at the primary location of the source. The cross shows the primary position of the source. Considering the centre of antenna as the antenna location, the localization error is 1.5 mm.

FIG. 6 shows the resolution of a diffraction-limited focal spot. The achieved resolution (i.e., the minimum spacing between sources that would allow them to be distinguished from each other) is about 12 mm. It should be noted that a resolution better than λₘᵢₙ/2 can be achieved by decreasing the hole size, however in a practical scenario, limited SNR of the sampling apparatus may limit the performance of the localisation.

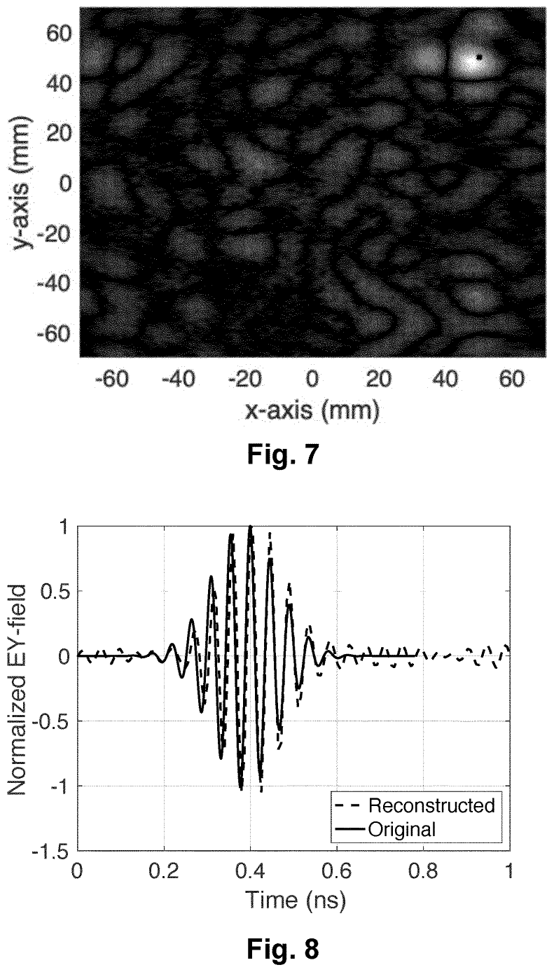

Herein, in order to ensure that the proposed method works for other polarisations, we considered the same source antenna, but we rotated it to be along the X-axis. It should be noted that similar to the first case scenario above, our probe antenna 3 is directed along the Y-axis. FIG. 7 shows the distribution of the normalised maximum of Eₓ in the plane of observation. The localisation error in this case is 2.6 mm. This result shows an effective conversion of polarisation of the mode-mixing cavity.

### Surface Current Reconstruction

We have seen that using the proposed system we are able to localise the electromagnetic radiation source. FIG. 8 compares the normalised excitation signal of the source with the normalised reconstructed waveform (field in backpropagation at the location of the source). It can be observed that the waveform can be recovered with a quite good precision.

Up to now, we showed that the proposed method can recover the field waveform at the location of the source 3. We now compare the field distribution at a surface in the vicinity of the source.

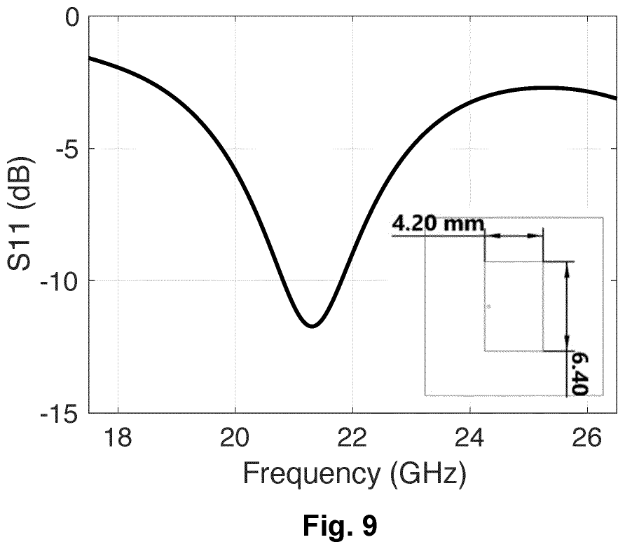

An X-polarised patch or microstrip antenna (i.e., the source 3) with a patch size of 6.4 mm (along the X-axis) and 4.2 mm (along the Y-axis) is placed at the distance of Z=60 mm from the front face of the cavity 9. The patch antenna and its return loss are shown in FIG. 9.

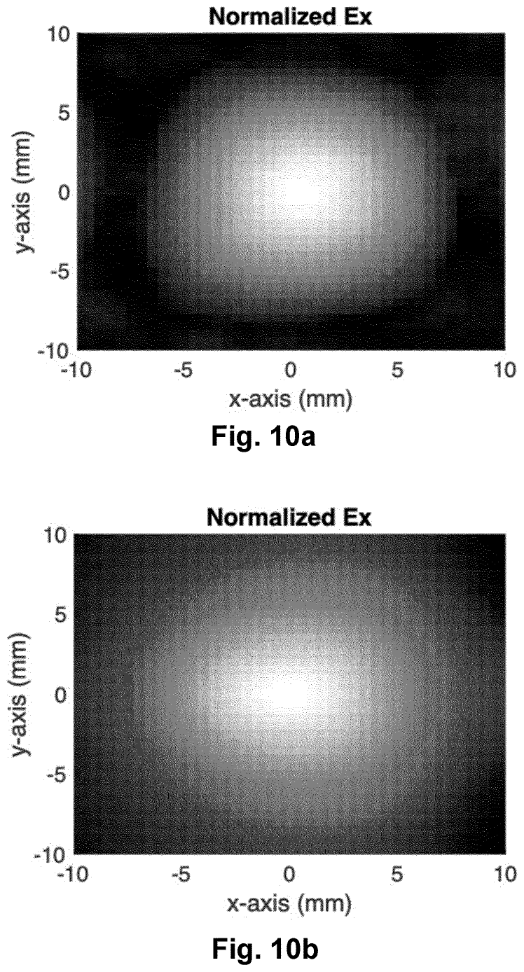

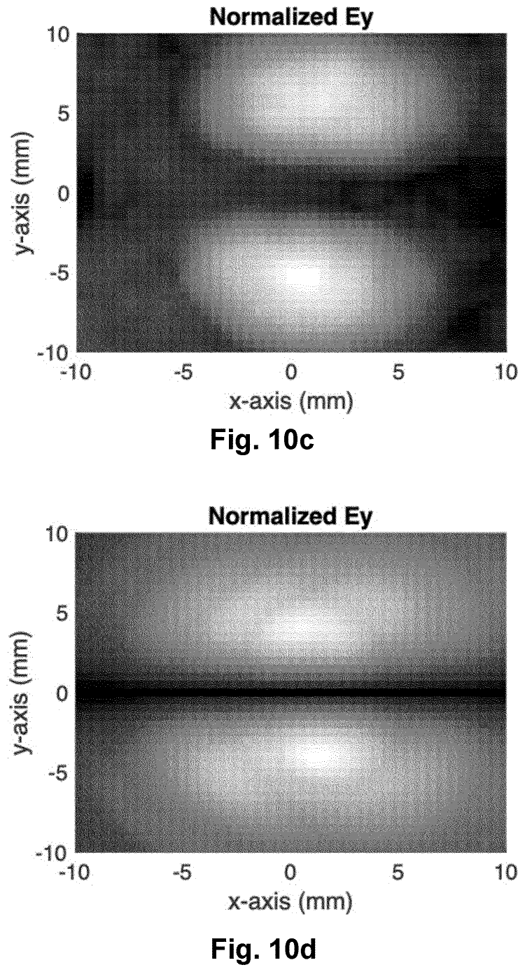

We compare the distribution of the normalised maximum electric field in the X-Y plane placed 5 mm from the plane of observation towards the sampling apparatus and the distribution of the estimated or reconstructed normalised maximum electric field in the plane of observation (Z=60 mm). FIGS. 10a and 10b show the results for the Eₓ field, while FIGS. 10c and 10d show the results for the E_{y} field. It can be seen that a fair agreement can be obtained for the distribution of the fields. The major difference between these two case studies is the fact that for the actual field, the near-field component is still present, while in the reconstructed field distribution, the evanescent field component (which is one of the near-field components, the other one being the radiation field component) is not present, due to the fact that the sensor 3 and cavity 9 are placed in the far field of the patch antenna.

### Far-Field Antenna Pattern Reconstruction

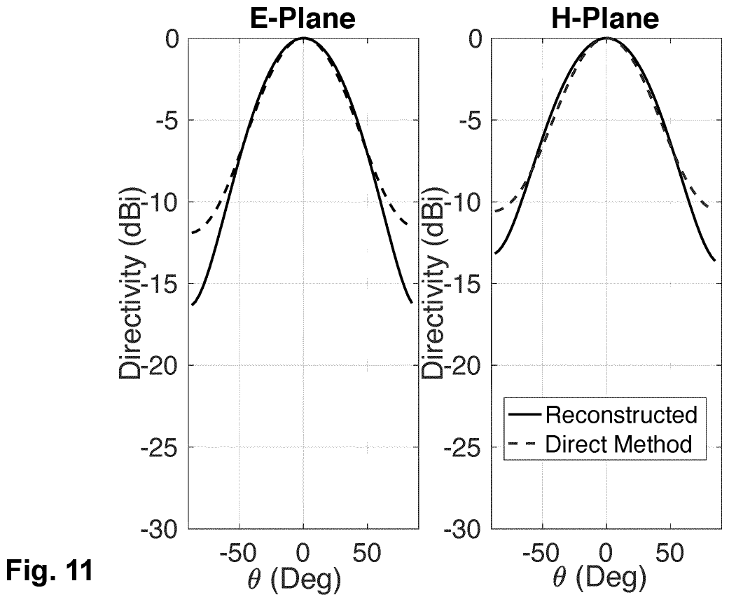

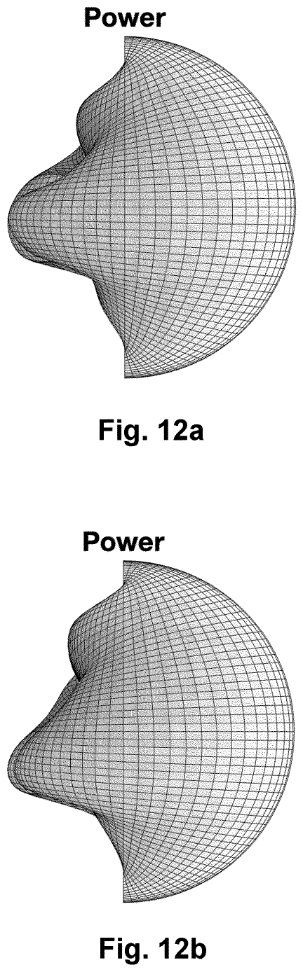

We next use the reconstructed field, and we use a near-field to far-field transformation to derive antenna directivity. In this example, we placed the patch antenna in the far field of the cavity (Z=60 mm). To do so, we recorded the reconstructed electric field at Z=60 mm. We apply a fast Fourier transform to derive the field distribution at the frequency of interest and we used a near-field to far-field transformation to calculate the field distribution in the far field to obtain the directivity pattern of the antenna 3. FIG. 11 shows the comparison of the directivity for direct calculations and for the reconstructed ones, at 21.5 GHz, while FIGS. 12a and 12b provide such a comparison for the 3D normalised total radiated power, where FIG. 12a shows the reference pattern, while FIG. 12b shows the reconstructed pattern.

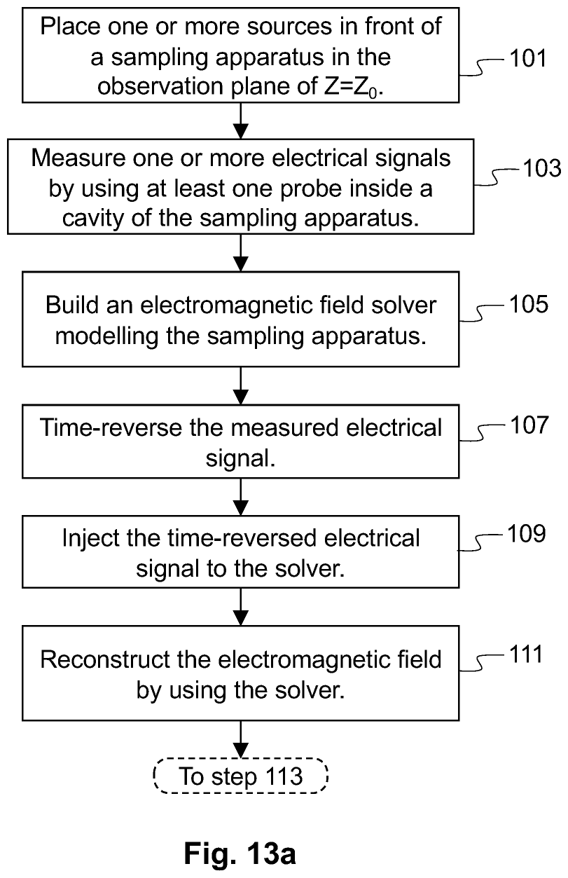

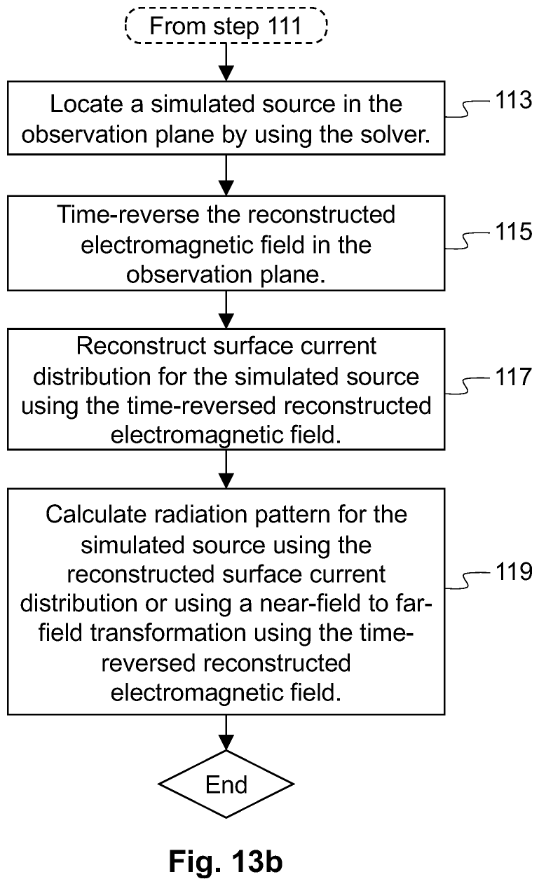

The flow chart of FIGS. 13a and 13b summarises the steps of the proposed source localisation and characterisation process. In step 101, one or more sources 3 (i.e., antennas in this case) are placed in front of the sampling apparatus 1 in the observation plane at a pre-defined distance from the front face 5 of the sampling apparatus. In step 103, the one or more sensors 13 inside the cavity 9 measure one or more electrical signals (with the amplitude of these signals given in voltages in the present example). These signals may thus be considered as (digital) electrical activity signals. It is to be noted that each sensor measures one electrical signal. Thus, the electrical signals measured by the different sensors may be somewhat different from each other. In this step one or more electrical signals are thus collected. In step 105, an electromagnetic field solver modelling the sampling apparatus is obtained. This step may also include calibrating the electromagnetic field solver with at least the dimensions and geometry of the sampling apparatus 1. In step 107, the measured or collected electrical signals are time-reversed, and in step 109, the time-reversed electrical signals are inputted to the electromagnetic field solver at simulated input locations. The method may optionally comprise carrying out a signal filtering operation on the one or more collected electrical signals and/or on the one or more time-reversed electrical signals prior to inputting the one or more time-reversed electrical signals into the electromagnetic field solver to improve the signal quality. It is to be noted that the one or more sensors are each located at a respective sensing location such that the one or more sensing locations may be understood to have a first spatial relationship (e.g., distance between the sensors) with respect to each other. The one or more time-reversed electrical signals may be arranged to be inputted into the electromagnetic field solver at a respective input location such that the one or more input locations may be understood to have a second spatial relationship with respect to each other, and where the first spatial relationship may be identical or substantially identical to the second spatial relationship. Thus, the time-reversed electrical signals 21 may be configured to be fed into the solver at different locations.

In step 111, the electromagnetic field solver reconstructs the electromagnetic field at least at a simulated or modelled observation plane corresponding (spatially) to the observation plane 11. For this purpose, the time-reversed electrical signals serve as input signals for the electromagnetic field solver. In step 113, the electromagnetic field solver locates one or more modelled or simulated sources in the simulated observation plane or in a simulated observation region. Each modelled source has its corresponding original source 3. The localisation of the one or more sources can be achieved by finding focal spot(s) in the simulated observation plane. The distribution of the maximum field can be used to achieve that. In other words, the focal spots may be identified by using a given identification criterium, wherein the identification criterium is a threshold value for the reconstructed electromagnetic field. In step 115, the reconstructed electromagnetic field is optionally time-reversed in the simulated observation plane. In step 117, a surface current distribution is reconstructed for the simulated source using the time-reversed reconstructed electromagnetic field (or the non-time-reversed reconstructed electromagnetic field if the time-reversed version of the field is not available). In step 119, a reconstructed (far-field) radiation pattern is calculated or determined for the one or more simulated sources using the reconstructed surface current distribution or using a near-field to far-field transformation using the time-reversed reconstructed electromagnetic field (or the non-time-reversed reconstructed electromagnetic field if the time-reversed version of the field is not available). It is to be noted that the reconstructed field in the observation plane can be seen as the near-field radiation component for the localised source. Using the well-known plane wave spectrum (PWS) method explained for instance in “Antenna theory: analysis and design”, by C. A. Balanis, John Wiley & Sons, 2005, vol. 1, it is then possible to calculate the far-field distribution for the localised source. The reconstructed surface current distribution technique is based on the surface equivalent principle as explained for example in “Time-Harmonic Electromagnetic Fields” by Harrington, Roger F., McGraw-Hill, Inc., 1961. Herein, we can define an imaginary surface S around the localised source. By knowing the reconstructed electric field and magnetic field in the observation plane and forcing the electric field and magnetic field inside S to be zero, we can obtain the surface equivalent currents as follows:

\vec{J}=\vec{n}×\vec{H}

\vec{M}=\vec{n}×\vec{E},

where \vec{J} denotes the electric current density, \vec{n} is the normal to the surface S, \vec{H} denotes the magnetic field, \vec{E} denotes the electric field, and \vec{M} denotes the magnetic current density. The electric field and magnetic field in the far-field region can be obtained by deriving the well-known electric field integral equation. Thus, the respective reconstructed far-field radiation pattern for the one or more modelled sources is directly or indirectly obtained from the reconstructed electromagnetic field.

As explained above, the present invention proposes a new hardware arrangement or system, and a single-shot spatial sampling method (where the electrical signals can be measured only once) to localise and characterise an electromagnetic source. The characterisation includes deriving an antenna radiation pattern based on a spatial sampling scheme. The mixing-mode property of the cavity is used to encode the information of the sampled electric field. As a proof of concept, we presented results for source localisation, surface current reconstruction and far-field pattern reconstruction. The proposed method can be used as a fast and cost-efficient solution for antenna pattern measurements and electromagnetic compatibility (EMC) testing.

Some of the above-described method steps may be carried out by suitable circuits or circuitry. The terms “circuits” and “circuitry” refer to physical electronic components or modules (e.g., hardware), and any software and/or firmware (“code”) that may configure the hardware, be executed by the hardware, and or otherwise be associated with the hardware. The circuits may thus be configured or operable to carry out, or they comprise means for carrying out, the required method as described above.

While the invention has been illustrated and described in detail in the drawings and foregoing description, such illustration and description are to be considered illustrative or exemplary and not restrictive, the invention being not limited to the disclosed embodiment. Other embodiments and variants are understood, and can be achieved by those skilled in the art when carrying out the claimed invention, based on a study of the drawings, the disclosure and the appended claims. For example, all or part of the computing (i.e., the data processing) according to the teachings of the present invention could be implemented as cloud computing by using computing power over the Internet.

In the claims, the word “comprising” does not exclude other elements or steps, and the indefinite article “a” or “an” does not exclude a plurality. The mere fact that different features are recited in mutually different dependent claims does not indicate that a combination of these features cannot be advantageously used. Any reference signs in the claims should not be construed as limiting the scope of the invention.

1. A method for localising and characterising one or more electromagnetic radiation sources, the method comprising the steps of:
collecting one or more electrical signals received from the one or more sources placed in an observation region in front of a sampling apparatus configured to measure the one or more electrical signals;
time-reversing the collected one or more electrical signals;
inputting the one or more time-reversed electrical signals into an electromagnetic field solver modelling the sampling apparatus and configured to solve Maxwell's equations;
determining a reconstructed electromagnetic field by running the electromagnetic field solver with the one or more time-reversed electrical signals as one or more input signals;
identifying one or more focal spots in the reconstructed electromagnetic field to thereby locate one or more modelled sources in a simulated observation region;
obtaining a respective reconstructed far-field radiation pattern for the one or more modelled sources directly or indirectly from the reconstructed electromagnetic field.

2. The method according to claim 1, wherein the one or more time-reversed electrical signals when inputted into the electromagnetic field solver converge at one or more convergence locations.

3. The method according to claim 1, wherein the method further comprises placing the one or more sources in front of the sampling apparatus in the observation region.

4. The method according to claim 1, wherein the one or more focal spots are identified by using a given identification criterium.

5. The method according to claim 1, wherein the respective reconstructed far-field radiation pattern is obtained by using a near-field to far-field transformation process by using the reconstructed electromagnetic field.

6. The method according to claim 1, wherein the respective reconstructed far-field radiation pattern is obtained by reconstructing a respective surface current distribution for the one or more modelled sources from the reconstructed electromagnetic field or from a time-reversed reconstructed electromagnetic field, and by using the respective reconstructed surface current distribution to obtain the respective reconstructed far-field radiation pattern.

7. The method according to claim 1, wherein the method further comprises calibrating the electromagnetic field solver with at least the dimensions and geometry of the sampling apparatus.

8. The method according to claim 1, wherein the sampling apparatus comprises a body with a cavity within the body, wherein the body comprises a perforated front wall with a set of holes and/or a metasurface, and facing the one or more sources, and wherein one or more sensors are placed in the cavity for measuring the one or more electrical signals.

9. The method according to claim 1, wherein the observation region forms an observation plane, and the simulated observation region forms a simulated observation plane.

10. The method according to claim 1, wherein the method further comprises carrying out a signal filtering operation on the one or more collected electrical signals and/or on the one or more time-reversed electrical signals prior to inputting the one or more time-reversed electrical signals into the electromagnetic field solver.

11. A non-transitory computer program product comprising instructions for implementing the steps of the method according to claim 1, when loaded and run on computing means of a computing device.

12. A sampling apparatus for sampling an electromagnetic field generated by one or more electromagnetic radiation sources placed in front of the sampling apparatus comprising a substantially closed body made of electrically conductive material and forming a cavity within the substantially closed body, the substantially closed body comprising a perforated front face comprising a set of holes and/or a metasurface forming a spatial field sampler for the electromagnetic field, and facing the one or more sources, wherein one or more sensors are located in the cavity for measuring one or more electrical signals.

13. The sampling apparatus according to claim 12, wherein the diameter of the holes is in the range of λₘᵢₙ/5 and λₘᵢₙ/2, wherein λₘᵢₙ denotes the minimum wavelength of electromagnetic signals generated by the one or more sources.

14. The sampling apparatus according to claim 12, wherein the set of holes forms a periodic array of holes.

15. The sampling apparatus according to claim 12, wherein the cavity is sized such that a first resonance frequency of the cavity is higher than the frequency range of the one or more sources.

16. A system for localising and characterising one or more electromagnetic radiation sources, the system being configured to perform operations comprising:
collect one or more electrical signals received from the one or more sources placed in an observation region in front of a sampling apparatus configured to measure the one or more electrical signals;
time-reverse the collected one or more electrical signals;
input the one or more time-reversed electrical signals into an electromagnetic field solver modelling the sampling apparatus, and configured to solve Maxwell's equations;
determine a reconstructed electromagnetic field by running the electromagnetic field solver with the one or more time-reversed electrical signals as one or more input signals;
identify one or more focal spots in the reconstructed electromagnetic field to thereby locate one or more modelled sources in a simulated observation region;
obtain a respective reconstructed far-field radiation pattern for the one or more modelled sources directly or indirectly from the reconstructed electromagnetic field.

17. The method according to claim 2, wherein identifying the one or more focal spots comprises detecting the one or more convergence locations.

18. The method according to claim 4, wherein the identification criterium is a threshold value for the reconstructed electromagnetic field.

19. The method according to claim 8, wherein one or more sensors are placed in the cavity for measuring the one or more electrical signals.

20. The sampling apparatus according to claim 12, wherein the cavity comprises one or more mode-mixing structures to enhance the mixing-mode nature of the cavity.
